(19) United States
(12) Patent Application Publication
(10) Pub. No.: US 2023/0263043 A1
(43) Pub. Date: Aug. 17, 2023

(54) APPARATUS AND METHOD FOR MANUFACTURING DISPLAY DEVICE

(71) Applicant: SAMSUNG DISPLAY CO., LTD., Yongin-si (KR)

(72) Inventors: Sunglae KIM, Yongin-si (KR); Deokheung KIM, Yongin-si (KR); Jeongmin BAE, Yongin-si (KR); Sanghoon BACK, Yongin-si (KR); Junseok AHN, Yongin-si (KR); Jaewoo LEE, Yongin-si (KR); Yeongho HA, Yongin-si (KR)

(21) Appl. No.: 18/110,796

(22) Filed: Feb. 16, 2023

(30) Foreign Application Priority Data
Feb. 17, 2022 (KR) 10-2022-0021040

(51) Int. Cl. H10K 71/50; H10K 59/12

(52) U.S. Cl. CPC H10K 71/50; H10K 59/1201; H10K 59/88

(57) ABSTRACT

An apparatus for manufacturing a display device includes: a stage where a display panel is arranged; a vision unit configured to capture images of an alignment mark of the display panel and an alignment mark of a film member; a fixing unit configured to transfer the film member and change a location of the film member based on the images captured by the vision unit such that an end of the film member is arranged on a pad portion of the display panel; and a loading unit connected to the fixing unit and configured to press the film member by selectively contacting the end of the film member.

This application claims priority to Korean Patent Application No. 10-2022-0021040, filed on Feb. 17, 2022, and all the benefits accruing therefrom under 35 U.S.C. § 119, the content of which in its entirety is herein incorporated by reference.

### BACKGROUND

### 1. Field

One or more embodiments relate to an apparatus and method, and more particularly, to an apparatus and method for manufacturing a display device.

### 2. Description of the Related Art

An electronic device based on mobility is widely used. A tablet personal computer (“PCs”), in addition to a small-sized electronic device such as a mobile phone, has been widely used as a mobile electronic device.

To support various functions, such a mobile electronic device includes a display panel to provide visual information, such as an image or a video, to a user. With the miniaturization of components for driving the display panel, proportions of the display panel occupying the electronic device are gradually increasing, and the display panel having a structure that is bendable from a flat state to have a certain angle is also being developed.

### SUMMARY

One or more embodiments include an apparatus and method for manufacturing a display device.

Additional aspects will be set forth in part in the description which follows and, in part, will be apparent from the description, or may be learned by practice of the presented embodiments of the disclosure.

According to one or more embodiments, an apparatus for manufacturing a display device includes: a stage where a display panel is arranged, a vision unit configured to capture images of an alignment mark of the display panel and an alignment mark of a film member, a fixing unit configured to transfer the film member and change a location of the film member based on the images captured by the vision unit such that an end of the film member is arranged in a pad portion of the display panel, and a loading unit connected to the fixing unit and configured to press the film member by selectively contacting the end of the film member.

The loading unit may include: a contacting portion to which the end of the film member is selectively fixed, a first linear driving unit configured to linearly move the contacting portion in a first direction by being connected to the contacting portion, and a second linear driving unit connected to the first linear driving unit and the fixing unit, and configured to linearly move the first linear driving unit in a second direction.

The contacting portion may include an adhesive chuck or a vacuum chuck.

The apparatus may further include a first head unit configured to apply heat and pressure to the film member by being disposed on an upper portion of the stage, and bond the film member to the display panel.

The apparatus may further include a second head unit spaced apart from the first head unit, and configured to apply heat and pressure to the film member and bond the film member to the display panel.

The first head unit and the second head unit may be arranged in a diagonal direction from each other with respect to a transfer direction of the stage.

The stage may include: a first main stage configured to move linearly, and a second main stage configured to move linearly and spaced apart from the first main stage.

A location of the first main stage and a location of the second main stage may independently change from each other.

A temperature applied by the first head unit to the film member may be different from a temperature applied by the second head unit to the film member.

The loading unit may apply heat to the film member.

According to one or more embodiments, a method of manufacturing a display device includes: contacting a film member to a display panel; pressing the film member while applying, by a first head unit, heat to the film member; and pressing the film member while applying, by a second head unit, heat to a portion of the film member pressed by the first head unit.

The method may further include: transferring the display panel to which the film member is attached, from one of the first head unit and the second head unit to another of the first head unit and the second head unit.

The first head unit and the second head unit may be arranged in a diagonal direction from each other with respect to a transfer direction of the display panel.

The method may further include capturing images of an alignment mark of the film member and an alignment mark of the display panel.

The method may further include changing a location of at least one of the film member or the display panel by comparing the alignment mark of the film member and the alignment mark of the display panel.

The method may further include pressing one surface of the film member by contacting a loading unit to the one surface of the film member.

The method may further include: separating the loading unit from the one surface of the film member after pressing the one surface of the film member.

The loading unit may include: a contacting portion to which an end of the film member is selectively fixed, a first linear driving unit configured to linearly move the contacting portion in a first direction by being connected to the contacting portion, and a second linear driving unit connected to the first linear driving unit and a fixing unit, and configured to linearly move the first linear driving unit in a second direction.

The contacting portion may include one of a vacuum chuck or an adhesive chuck, which fixes the one surface of the film member.

A temperature of the first head unit may be different from a temperature of the second head unit.

Other aspects, features, and advantages may become clear from the following drawings, the claims, and the detailed description of the disclosure.

These general and specific aspects may be practiced using a system, method, computer program, or any combination of systems, methods, and computer programs.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically showing an apparatus for manufacturing a display device, according to an embodiment;

FIGS. 2A through 2E are front views for describing a method of manufacturing the display device of FIG. 1;

FIG. 3 is a plan view schematically showing a display device according to an embodiment;

FIG. 4 is a side view schematically showing a portion of the display device of FIG. 3; and

FIG. 5 is a cross-sectional view schematically showing a portion of a display panel of FIG. 3.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may have various modifications and various embodiments, and specific embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

Hereinafter, embodiments of the disclosure will be described in detail with reference to the accompanying drawings, and in the following description with reference to the drawings, like reference numerals refer to like elements and redundant descriptions thereof will be omitted.

In the following embodiments, the terms “first” and “second” are not used in a limited sense and are used to distinguish one component from another component.

In the following embodiments, an expression used in the singular encompasses the expression of the plural, unless it has a clearly different meaning in the context.

It will be further understood that the terms “comprise” and/or “comprising” used herein specify the presence of stated features or elements, but do not preclude the presence or addition of one or more other features or elements.

It will be understood that when a layer, region, or element is referred to as being “formed on” another layer, area, region or element, it can be directly or indirectly formed on the other layer, region, or element. That is, for example, intervening layers, regions, or elements may be present.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

According to embodiments, an X-axis, a Y-axis, and a Z-axis are not limited to three axes on an orthogonal coordinate system, but may be interpreted in a broad sense including the three axes. For example, the X-axis, the Y-axis, and the Z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

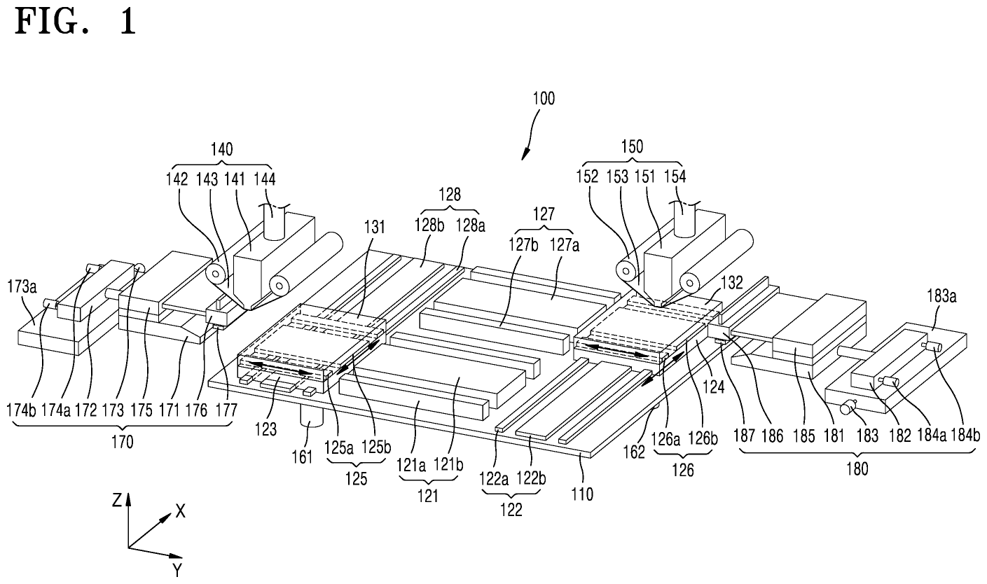

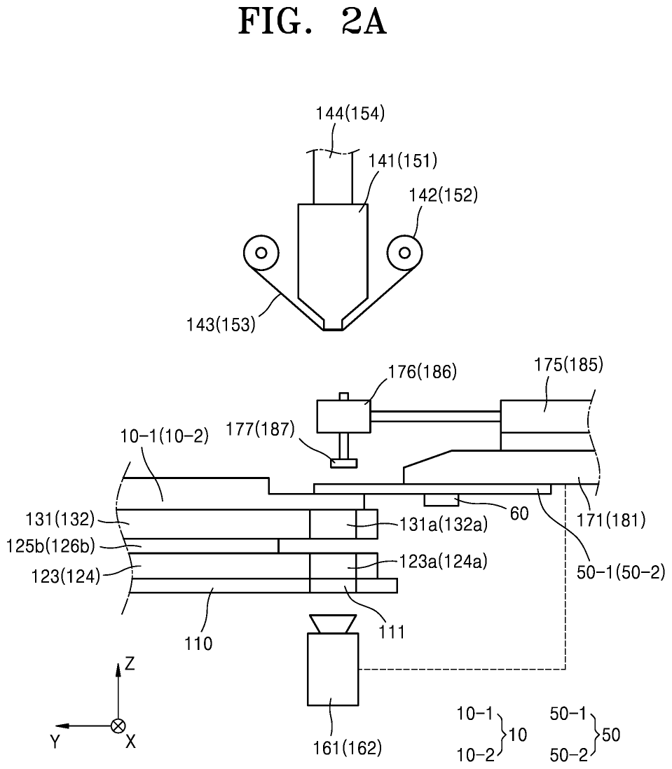

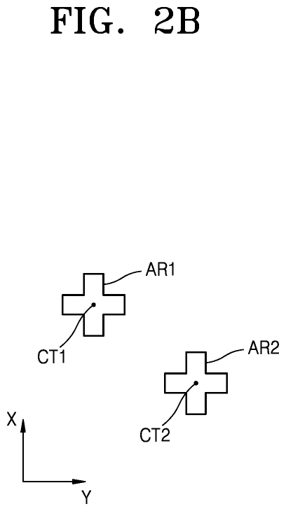

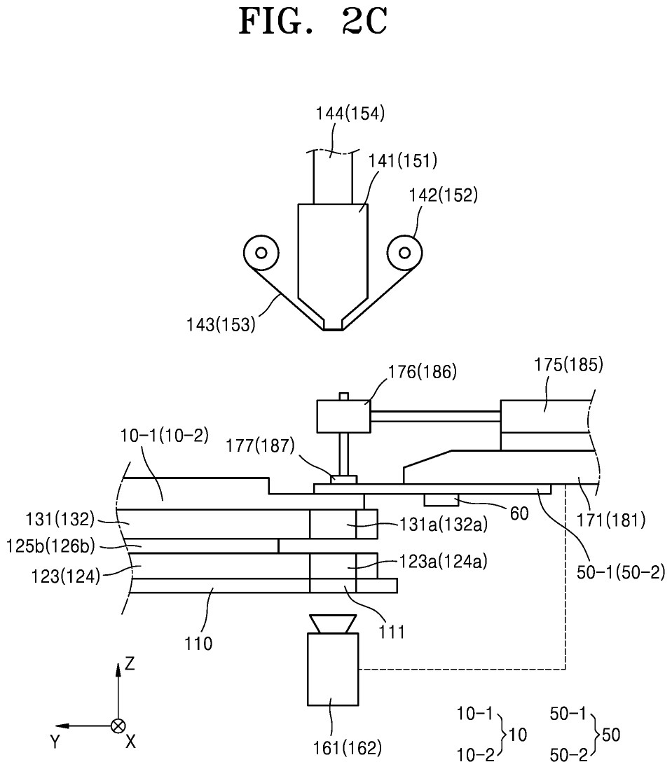

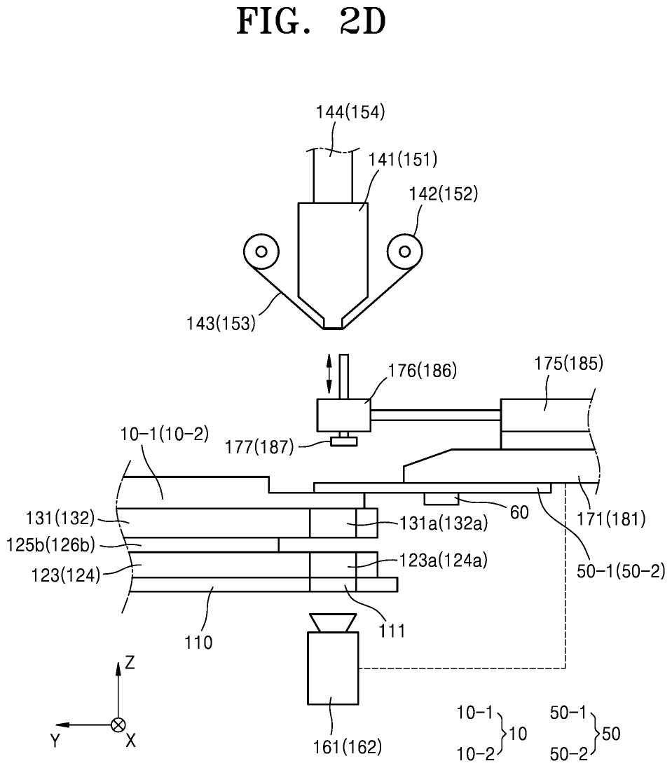

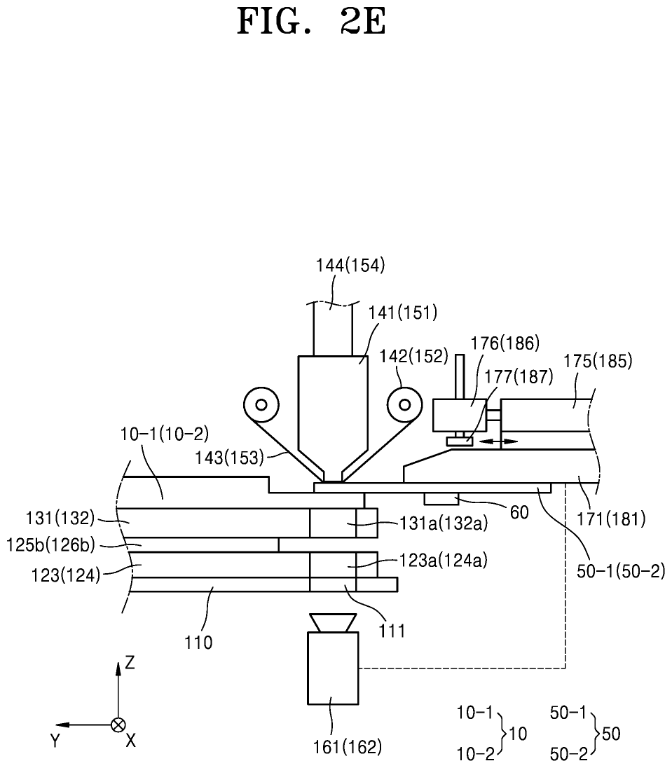

FIG. 1 is a perspective view schematically showing an apparatus 100 for manufacturing a display device, according to an embodiment. FIGS. 2A through 2E are front views for describing a method of manufacturing the display device of FIG. 1.

Referring to FIGS. 1 through 2E, the apparatus 100 may include a support portion 110, a first driving unit 121, a second driving unit 122, a first stage 123, a second stage 124, a third driving unit 125, a fourth driving unit 126, a fifth driving unit 127, a sixth driving unit 128, a first main stage 131, a second main stage 132, a first head unit 140, a second head unit 150, a first vision unit 161, a second vision unit 162, a first transfer unit 170, and a second transfer unit 180.

The support portion 110 may have a plate shape. According to another embodiment, the support portion 110 may include a plate and a plurality of bars for supporting the plate. According to another embodiment, the support portion 110 may include various members, such as a wall surface of a building, a floor of a building, an external surface of another apparatus, or the like.

The first driving unit 121 is disposed on the support portion 110. The first driving unit 121 may be configured to linearly move the first stage 123 in a first direction (for example, a Y-axis direction of FIG. 1). Here, the first driving unit 121 may include a first guide 121a and a first driving power generation unit 121b. In this case, the first guide 121a may include a linear motion guide. The first driving power generation unit 121b may be in any one of various forms. According to an embodiment, the first driving power generation unit 121b may include an electromagnet of a linear motor. According to another embodiment, the first driving power generation unit 121b may include a screw, a motor connected to the screw, and a motion block for moving linearly on the screw. Here, an electromagnet may be arranged in the motion block to selectively restrain the first stage 123. According to another embodiment, the first driving power generation unit 121b may be able to move the first stage 123 in the first direction in a magnetic levitation manner.

The first driving unit 121 may also be configured to move the second main stage 132 in the first direction (for example, a Y-axis direction of FIG. 1), in addition to the first main stage 131. The first driving unit 121 is illustrated that a pair of first guides 121a are provided and the first driving power generation unit 121b is arranged between the first guides 121a, but the first driving unit 121 is not limited thereto, and may include a pair of first driving power generation units 121b spaced apart from each other and the first guide 121a arranged between the first driving power generation units 121b in another embodiment.

The second driving unit 122 may be arranged in a direction different from the arranged direction of the first driving unit 121. Here, the second driving unit 122 may move the second stage 124 in a second direction (for example, an X-axis direction of FIG. 1). The second driving unit 122 may include a second guide 122a and a second driving power generation unit 122b. In this case, the second guide 122a and the second driving power generation unit 122b may be the same as or similar to the first guide 121a and the first driving power generation unit 121b described above.

The first stage 123 may move in the second direction (for example, an X-axis direction of FIG. 1) while supporting the first main stage 131 or the second main stage 132 thereunder. Also, the first stage 123 may have a plate shape. Although not illustrated, magnets may be arranged on a bottom surface of the first stage 123 to correspond to a sixth driving power generation unit 128b described below, or a magnetic body may be arranged on the bottom surface of the first stage 123. Also, a block combined to a sixth guide 128a may be arranged on the bottom surface of the first stage 123.

The second stage 124 may be spaced apart from the first stage 123. Here, the second stage 124 may move while supporting the first main stage 131 or the second main stage 132 thereunder. The second stage 124 has the same or similar shape as that of the first stage 123, and thus details thereof are not provided.

The third driving unit 125 may be disposed on an upper portion of the first stage 123. Here, the third driving unit 125 may include a third guide 125a and a third driving power generation unit 125b. The third guide 125a and the third driving power generation unit 125b are the same as or similar to the first guide 121a and the first driving power generation unit 121b, and thus details thereof are not provided.

The third guide 125a and the third driving power generation unit 125b may be arranged at same heights as the first guide 121a and the first driving power generation unit 121b, respectively. For example, a distance from a top surface of the support portion 110 to a top surface of the first guide 121a may be the same as a distance from the top surface of the support portion 110 to a top surface of the third guide 125a. Also, the first driving power generation unit 121b and the third driving power generation unit 125b may be arranged to have a relationship similar to that between the first guide 121a and the third guide 125a.

The fourth driving unit 126 may be disposed on the second stage 124. The fourth driving unit 126 may include a fourth guide 126a and a fourth driving power generation unit 126b. The fourth guide 126a and the fourth driving power generation unit 126b are the same as or similar to the first guide 121a and the first driving power generation unit 121b, respectively, and thus details thereof are not provided.

The fifth driving unit 127 may be arranged in a same direction (e.g., first direction) as the first driving unit 121. The fifth driving unit 127 may include a fifth guide 127a and a fifth driving power generation unit 127b. The fifth guide 127a and the fifth driving power generation unit 127b may have the same or similar shapes as those of the first guide 121a and the first driving power generation unit 121b, respectively.

The sixth driving unit 128 may be arranged in a direction different from the fifth driving unit 127. For example, the sixth driving unit 128 may be arranged in a same direction (e.g., second direction) as the second driving unit 122. Here, the sixth driving unit 128 may move the first stage 123 linearly in the second direction (for example, an X-axis direction of FIG. 1). The sixth driving unit 128 may include the sixth guide 128a and the sixth driving power generation unit 128b. The sixth guide 128a and the sixth driving power generation unit 128b may have the same or similar shapes as those of the first guide 121a and the first driving power generation unit 121b, respectively.

The first main stage 131 may circulate along an outer perimeter of the support portion 110. Here, the first main stage 131 may move linearly along an operation of each driving unit. For example, the first main stage 131 may move to circulate along the first driving unit 121, the fourth driving unit 126, the fifth driving unit 127, and the second driving unit 122.

In this case, the first main stage 131 may be formed in any one of various manners. For example, the first main stage 131 may include an align stage or UVW stage configured to precisely adjust a location of a display panel 10 arranged in the first main stage 131. According to another embodiment, the first main stage 131 may be in a general plate shape. In this case, the first main stage 131 may include a vacuum chuck including a suction hole to fix the display panel 10, or may include an adhesive chuck or electrostatic chuck.

The second main stage 132 may be spaced apart from the first main stage 131 and circulate along the outer perimeter of the support portion 110. For example, the second main stage 132 may move to circulate along the first driving unit 121, the fourth driving unit 126, the fifth driving unit 127, and the second driving unit 122. Here, the second main stage 132 may be formed to be the same as or similar to the first main stage 131. In this case, motion of the first main stage 131 and motion of the second main stage 132 may be synchronized and symmetrical, and thus the first main stage 131 and the second main stage 132 may move in a same distance and direction. In particular, when the first main stage 131 is disposed on the third driving unit 125, the second main stage 132 may be disposed on the fourth driving unit 126. Alternatively, when the first main stage 131 is disposed on the fourth driving unit 126, the second main stage 132 may be disposed on the third driving unit 125.

The first head unit 140 and the second head unit 150 may be arranged in a diagonal direction with each other. In this case, the first head unit 140 and the second head unit 150 may be able to simultaneously operate different display panels 10. In particular, when one of the first head unit 140 and the second head unit 150 is arranged to face one of the first main stage 131 or the second main stage 132, the other one of the first head unit 140 and the second head unit 150 may be arranged to face the other one of the first main stage 131 and the second main stage 132. The first head unit 140 and the second head unit 150 are formed in the same or similar manner, and thus hereinafter, the first head unit 140 will be mainly described in detail for convenience of description.

The first head unit 140 may be arranged in a first area and attach the display panel 10 and a film member 50. According to an embodiment, the first head unit 140 may include a first head body 141 and a first head driving unit 144. According to another embodiment, the first head unit 140 may include the first head body 141, a first protection member 143, a first tension roller 142, and the first head driving unit 144. Hereinafter, for convenience of description, a case where the first head unit 140 includes the first head body 141, the first protection member 143, the first tension roller 142, and the first head driving unit 144 will be mainly described in detail.

A portion of the first head body 141 may be formed to protrude. In this case, the first head body 141 may press the film member 50 and at the same time, apply heat to the film member 50. For example, the first head body 141 may include a heater arranged therein, and a temperature of the first head body 141 may change by the heater.

The first protection member 143 may be arranged between the film member 50 and the first head body 141, and make pressure applied to the film member 50 uniform when the first head body 141 contacts the film member 50.

The first tension roller 142 not only maintains tension of the first protection member 143, but also adheres the first protection member 143 close to the protruding portion of the first head body 141. In this case, the first tension roller 142 may be arranged at each end of the first protection member 143 to apply tension to the first protection member 143.

The first head driving unit 144 may be connected to the first head body 141 and configured to raise or lower the first head body 141. Here, the first head driving unit 144 may include various devices. For example, the first head driving unit 144 may include a cylinder, a linear motor, or a ball screw and a motor.

The second head unit 150 may include a second head body 151, a second protection member 153, a second tension roller 152, and a second head driving unit 154. Here, the second head body 151, the second protection member 153, the second tension roller 152, and the second head driving unit 154 may be the same as or similar to the first head body 141, the first protection member 143, the first tension roller 142, and the first head driving unit 144, respectively.

The first vision unit 161 and the second vision unit 162 may be arranged to correspond to the first head unit 140 and the second head unit 150, respectively. Because the first vision unit 161 and the second vision unit 162 are similar, the first vision unit 161 will be mainly described in detail for convenience of description.

The first vision unit 161 may include a camera. Here, the first vision unit 161 may be disposed below the support portion 110, the first stage 123, and the first main stage 131 to capture images of a first alignment mark AR1 of the display panel 10 and a second alignment mark AR2 of the film member 50. Although the images captured by the first vision unit 161 are not illustrated, the images may be transmitted to a control unit and the control unit may change a location of the film member 50 and/or a location of the display panel 10, based on the images.

The first transfer unit 170 (e.g., first fixing unit 171) may not only transfer the film member 50, but also adjust the location of the film member 50 in real time. Also, the first transfer unit 170 (e.g., first contacting portion 177) may temporarily press the film member 50 such that the film member 50 is temporarily bonded to the display panel 10. The second transfer unit 180 (e.g., second fixing unit 181) may not only transfer the film member 50, but also adjust the location of the film member 50 in real time. Also, the second transfer unit 180 (e.g., second contacting portion 187) may temporarily press the film member 50 such that the film member 50 is temporarily bonded to the display panel 10. For example, the first fixing unit 171 or the second fixing unit 181 may transfer the film member 50 and change a location of the film member 50 based on the images captured by the first vision unit 161 such that an end of the film member 50 is arranged on a pad portion of the display panel 10.

The first transfer unit 170 and the second transfer unit 180 may be the same or similar. Hereinafter, for convenience of description, the first transfer unit 170 will be mainly described in detail.

The first transfer unit 170 may include a first fixing unit 171, a (1-1)th linear driving unit 172, a (1-1)th alignment driving unit 173, a (1-2)th alignment driving unit 174a, a (1-3)th alignment driving unit 174b, a (1-2)th linear driving unit 175, a (1-3)th linear driving unit 176, and a first contacting portion 177.

The first fixing unit 171 may linearly move and configured to fix the film member 50. Here, a vacuum chuck or an adhesive chuck may be provided at a bottom surface of the first fixing unit 171 to fix the film member 50. A top surface of an end of the first fixing unit 171 may be formed to incline.

The (1-1)th linear driving unit 172 may be connected to the first fixing unit 171 and configured to linearly move the first fixing unit 171 in the first direction (for example, a Y-axis direction of FIG. 1). The (1-1)th linear driving unit 172 may have any one of various shapes. For example, the (1-1)th linear driving unit 172 may include a cylinder, a linear motor, a ball screw and a motor, a motor and a rack gear, or a robot arm including a plurality of joints and a frame. In this case, the (1-1)th linear driving unit 172 may be connected to the first fixing unit 171. The (1-1)th linear driving unit 172 may linearly move in the first direction and/or the second direction. In this case, the (1-1)th linear driving unit 172 may linearly move by being arranged at a separately provided guide or the like.

The (1-1)th alignment driving unit 173 may be connected to the (1-1)th linear driving unit 172 and configured to linearly move the (1-1)th linear driving unit 172 in the second direction (for example, an X-axis direction of FIG. 1). Here, the (1-1)th alignment driving unit 173 may be connected to a separate first connection plate 173a connected to a bottom portion of the (1-1)th linear driving unit 172 to linearly move the first connection plate 173a in the second direction, thereby linearly moving the (1-1)th linear driving unit 172. In this case, the (1-1)th linear driving unit 172 may be rotatably connected to the first connection plate 173a.

The (1-2)th alignment driving unit 174a and the (1-3)th alignment driving unit 174b may be fixed to the first connection plate 173a and connected to the (1-1)th linear driving unit 172. Here, when the (1-2)th alignment driving unit 174a and the (1-3)th alignment driving unit 174b operate, the (1-1)th linear driving unit 172 may be rotated on the first connection plate 173a, thereby rotating the first fixing unit 171.

The (1-1)th alignment driving unit 173, the (1-2)th alignment driving unit 174a, and the (1-3)th alignment driving unit 174b have the same or similar shapes as that of the (1-1)th linear driving unit 172 described above, and thus detailed descriptions thereof are not provided.

The (1-2)th linear driving unit 175 may be disposed on the first fixing unit 171. Here, the (1-2)th linear driving unit 175 may be connected to the (1-3)th linear driving unit 176 and the first fixing unit 171, and configured to linearly move the (1-3)th linear driving unit 176 in the first direction (for example, a Y-axis direction of FIG. 1). The (1-2)th linear driving unit 175 is the same as or similar to the (1-1)th linear driving unit 172, and thus detailed descriptions thereof are not provided.

The (1-3)th linear driving unit 176 may be connected to the first contacting portion 177 and configured to linearly move the first contacting portion 177 in a third direction (for example, a Z-axis direction of FIG. 1). The (1-3)th linear driving unit 176 is the same as or similar to the (1-1)th linear driving unit 172, and thus detailed descriptions thereof are not provided.

The first contacting portion 177 may be arranged at an end of the (1-3)th linear driving unit 176 and linearly move according to an operation of the (1-3)th linear driving unit 176. Here, the first contacting portion 177 may have a plate shape and include a heater or the like to apply heat. The first contacting portion 177 may not only press the film member 50, but also apply heat to the film member 50, thereby temporarily bonding the film member 50 and the display panel 10.

The second transfer unit 180 may include a second fixing unit 181, a (2-1)th linear driving unit 182, a (2-1)th alignment driving unit 183, a second connection plate 183a, a (2-2)th alignment driving unit 184a, a (2-3)th alignment driving unit 184b, a (2-2)th linear driving unit 185, a (2-3)th linear driving unit 186, and a second contacting portion 187. The second fixing unit 181, the (2-1)th linear driving unit 182, the (2-1)th alignment driving unit 183, the second connection plate 183a, the (2-2)th alignment driving unit 184a, the (2-3)th alignment driving unit 184b, the (2-2)th linear driving unit 185, the (2-3)th linear driving unit 186, and the second contacting portion 187 are the same as or similar to the first fixing unit 171, the (1-1)th linear driving unit 172, the (1-1)th alignment driving unit 173, the first connection plate 173a, the (1-2)th alignment driving unit 174a, the (1-3)th alignment driving unit 174b, the (1-2)th linear driving unit 175, the (1-3)th linear driving unit 176, and the first contacting portion 177 described above, respectively, and thus detailed descriptions thereof are not provided.

Although not illustrated, the first transfer unit 170 and the second transfer unit 180 may be connected to the first main stage 131 and the second main stage 132, respectively, and move together with the first main stage 131 and the second main stage 132, respectively, when the first main stage 131 and the second main stage 132 move.

Referring to a method of adhering the film member 50 and the display panel 10 through the apparatus 100 described above, first, two display panels 10 may be arranged on the first main stage 131 and the second main stage 132, respectively. Hereinafter, for convenience of description, the display panel 10 arranged on the first main stage 131 will be referred to as a first display panel 10-1, and the display panel 10 arranged on the second main stage 132 will be referred to as a second display panel 10-2.

A robot arm or the like may be used to arrange the first display panel 10-1 on the first main stage 131 or arrange the second display panel 10-2 on the second main stage 132.

When the first display panel 10-1 and the second display panel 10-2 are arranged as above, the first main stage 131 and the second main stage 132 may be arranged in a diagonal direction with each other in a plan view. In other words, the first main stage 131 and the second main stage 132 may be disposed at bottom portions of the first head unit 140 and the second head unit 150, respectively. Here, the “plan view” may be defined as a view in a Z-axis direction of FIG. 1.

The first transfer unit 170 and the second transfer unit 180 may simultaneously transfer different film members 50. Hereinafter, for convenience of description, the film member 50 transferred by the first transfer unit 170 will be referred to as a first film member 50-1, and the film member 50 transferred by the second transfer unit 180 will be referred to as a second film member 50-2.

The first transfer unit 170 may arrange the first film member 50-1 to correspond to the first display panel 10-1 (e.g., pad portion of the first display panel 10-1), and the second transfer unit 180 may arrange the second film member 50-2 to correspond to the second display panel 10-2 (e.g., pad portion of the second display panel 10-2).

Referring to FIG. 2A, the first contacting portion 177 may not contact the first film member 50-1, and the second contacting portion 187 may not contact the second film member 50-2. Here, the first vision unit 161 and the second vision unit 162 may capture images of a bottom surface of the first display panel 10-1 and a bottom surface of the second display panel 10-2, respectively. A method by which the first vision unit 161 captures an image and a method by which the second vision unit 162 captures an image are similar, and thus the method by which the first vision unit 161 captures an image will be described in detail.

When the first vision unit 161 captures an image, the support portion 110, the first stage 123, and the first main stage 131 may be at least partially formed of transparent materials such that an image of the bottom surface of the first display panel 10-1 is captured. For example, the support portion 110, the first stage 123, and the first main stage 131 may be entirely formed of transparent materials. As another example, transparent windows formed of transparent materials may be arranged at portions of the support portion 110, the first stage 123, and the first main stage 131. Hereinafter, for convenience of description, a case where the support portion 110, the first stage 123, and the first main stage 131 each include a transparent window will be mainly described in detail.

The first stage 123 may include a first stage transparent window 123a arranged at an end of the first stage 123. Also, the first main stage 131 may include a first main stage transparent window 131a arranged at an end of the first main stage 131. The support portion 110 may include a support portion transparent window 111 at a portion corresponding to the first head unit 140. In this case, the first stage transparent window 123a, the first main stage transparent window 131a, and the support portion transparent window 111 are arranged in a line such that the first vision unit 161 may capture an image of the bottom surface of the first display panel 10-1.

The second stage 124 and the second main stage 132 may include a second stage transparent window 124a and a second main stage transparent window 132a, respectively. Also, the support portion transparent window 111 may be arranged at a portion of the support portion 110, which correspond to the second stage transparent window 124a and the second main stage transparent window 132a.

A method of arranging the first display panel 10-1 and the first film member 50-1 and a method of arranging the second display panel 10-2 and the second film member 50-2 are similar, and thus the method of arranging the first display panel 10-1 and the first film member 50-1 will be described in detail below.

In addition to the above, when the first film member 50-1 is transferred, the first contacting portion 177 may contact an end portion of the first film member 50-1 as shown in FIG. 2C while the first film member 50-1 is transferred. In this case, the first contacting portion 177 may include a vacuum chuck or an adhesive chuck to fix the end portion of the first film member 50-1. However, for convenience of description below, a case where the first contacting portion 177 is spaced apart from the end portion of the first film member 50-1 when the first film member 50-1 is transferred will be mainly described in detail.

Referring to FIG. 2B, the first vision unit 161 may capture an image of the end portion of the first display panel 10-1. Here, light may pass through the end portion of the first display panel 10-1. Light may also pass through an end portion of the first film member 50-1 overlapping the end portion of the first display panel 10-1 in a plan view. Accordingly, the first vision unit 161 may capture the images of the first alignment mark AR1 of the first display panel 10-1 and the second alignment mark AR2 of the first film member 50-1.

In an embodiment, a location of at least one of the first film member 50-1 and the first display panel 10-1 may be changed by comparing the images of the second alignment mark AR2 of the first film member 50-1 and the first alignment mark AR1 of the first display panel 10-1. The images captured by the first vision unit 161 may be transmitted to the control unit, and the control unit may determine whether the first display panel 10-1 and the first film member 50-1 are arranged at accurate locations, based on the images. For example, when shapes of the first alignment mark AR1 and the second alignment mark AR2 are the same as shown in FIG. 2B according to an embodiment, the control unit may determine that the first film member 50-1 and the first display panel 10-1 are arranged at pre-set locations when the first alignment mark AR1 and the second alignment mark AR2 completely overlap in a plan view or a distance between edges is within a pre-set range, in the images captured by the first vision unit 161. In this case, the control unit may perform following operations. According to another embodiment, although not illustrated, when the shapes of the first alignment mark AR1 and the second alignment mark AR2 are different, the control unit may calculate a first center CT1 of the first alignment mark AR1 and a second center CT2 of the second alignment mark AR2 from the images captured by the first vision unit 161. Then, the control unit may determine that the first film member 50-1 and the first display panel 10-1 are arranged at the pre-set locations when the first center CT1 and the second center CT2 completely match each other or a distance between the first center CT1 and the second center CT2 is within a pre-set range.

On the other hand, the control unit may determine that the first film member 50-1 and the first display panel 10-1 are not aligned when, as shown in FIG. 2B, the first alignment mark AR1 and the second alignment mark AR2 do not overlap each other in a plan view while an edge of the first alignment mark AR1 and an edge of the second alignment mark AR2 are spaced apart from each other by a certain distance or greater, or when the first center CT1 and the second center CT2 do not match each other and are spaced apart from each other by a certain distance or greater.

In this case, the control unit may control the sixth driving unit 128, the first main stage 131, the (1-1)th linear driving unit 172, the (1-2)th linear driving unit 175, the (1-3)th linear driving unit 176, the (1-1)th alignment driving unit 173, the (1-2)th alignment driving unit 174a, and/or the (1-3)th alignment driving unit 174b so as to adjust the location of the first film member 50-1 or the first display panel 10-1.

The above operations may be performed in real time while continuously monitoring the operations through the first vision unit 161. Also, the first alignment mark AR1 and the second alignment mark AR2 may be provided as a pair so as to identify a space between the first display panel 10-1 and the first film member 50-1 in the first direction and/or the second direction, and dislocation of the first film member 50-1 with respect to the first display panel 10-1.

Referring to FIG. 2C, when it is determined that the location of the first display panel 10-1 and the location of the first film member 50-1 correspond to the pre-set locations, the control unit may operate the (1-2)th linear driving unit 175 to linearly move the first contacting portion 177 in the first direction (for example, a Y-axis direction of FIG. 1). Then, when a location of the first contacting portion 177 reaches a pre-set location, the (1-3)th linear driving unit 176 may be operated to lower the first contacting portion 177 such that the first contacting portion 177 contacts the first film member 50-1. Also, the first contacting portion 177 may apply uniform pressure to the first film member 50-1. Also, the first contacting portion 177 may apply heat to the first film member 50-1 so as to temporarily bond the first film member 50-1 to the first display panel 10-1. Here, a separate anisotropic conductive film may be arranged between the first film member 50-1 and the first display panel 10-1 to connect the first film member 50-1 and the first display panel 10-1 to each other, or some of the first film member 50-1 and/or the first display panel 10-1 may be melted to connect the first film member 50-1 and the first display panel 10-1 to each other.

According to another embodiment, when the first contacting portion 177 has fixed the end portion of the first film member 50-1 when the first film member 50-1 is transferred, only the (1-3)th linear driving unit 176 may be operated to slightly lower the first contacting portion 177 than before while the first film member 50-1 temporarily bonds the first display panel 10-1.

When the first contacting portion 177 presses the first film member 50-1 as described above, the end portion of the first film member 50-1 may become even. In addition, the first contacting portion 177 may apply heat to the first film member 50-1, thereby reducing distortion of the first film member 50-1.

Referring to FIG. 2D, the (1-3)th linear driving unit 176 may be operated to raise the first contacting portion 177 after the end portion of the first film member 50-1 and the end portion of the first display panel 10-1 are temporarily bonded to each other. Also, the (1-2)th linear driving unit 175 may move the first contacting portion 177 backwards as shown in FIG. 2E. Here, the (1-2)th linear driving unit 175, the (1-3)th linear driving unit 176, and the first contacting portion 177 may be collectively called as a “loading unit”.

Referring to FIG. 2E, when the first contacting portion 177 ascends and then moves backwards, a space for the first head unit 140 to descend may be provided. In this case, the first head driving unit 144 may be operated to lower the first head body 141. Here, the first protection member 143 may also descend together with the first head body 141. In this case, the first tension roller 142 may descend together with the first head body 141 or may extract the first protection member 143.

When the first protection member 143 contacts the first film member 50-1, the first head body 141 may press the first film member 50-1. At this time, a temperature of the first head body 141 may be a first temperature (or a first temperature range that is a pre-set temperature range). Also, the first head body 141 may press the first film member 50-1 with first pressure (or first force). In this case, the first film member 50-1 may be primarily bonded to the first display panel 10-1.

While the above operation is performed, the second head unit 150 and the second transfer unit 180 may bond the second display panel 10-2 and the second film member 50-2 in the same manner as the first head unit 140 and the first transfer unit 170 bond the first display panel 10-1 and the first film member 50-1. Here, a temperature of the second head body 151 may be the same as or similar to the first temperature (or the first temperature range) of the first head body 141. Also, pressure (or force) applied by the second head body 151 to the second film member 50-2 may be the same as or similar to the first pressure (or the first force).

When the above operations are completed, the first main stage 131 may move in the first direction (for example, a Y-axis direction of FIG. 1) along the third driving unit 125 and the first driving unit 121, and the second main stage 132 may move in a direction opposite to the first direction along the fourth driving unit 126 and the fifth driving unit 127.

When the first main stage 131 is not disposed on the first stage 123, the sixth driving unit 128 may move the first stage 123 in the second direction. When the second main stage 132 is not disposed on the second stage 124, the second driving unit 122 may move the second stage 124 in the second direction (for example, an X-axis direction of FIG. 1).

Then, when the first main stage 131 is disposed on the fourth driving unit 126 after passing through the first driving unit 121, the first main stage 131 may be disposed on the second stage 124. Also, when the second main stage 132 is disposed on the third driving unit 125 after passing through the fifth driving unit 127, the second main stage 132 may be disposed on the first stage 123.

The second driving unit 122 may dispose the second stage 124 on the bottom portion of the first head unit 140, and the sixth driving unit 128 may dispose the first stage 123 on the bottom portion of the second head unit 150.

As such, when the first main stage 131 and the second main stage 132 move, the first transfer unit 170 and the second transfer unit 180 may move together with the first main stage 131 and the second main stage 132.

When the first main stage 131 and the second main stage 132 move, the first contacting portion 177 may be contacting the first film member 50-1 and the second contacting portion 187 may be contacting the second film member 50-2. According to another embodiment, when the first main stage 131 and the second main stage 132 move, the first contacting portion 177 may not be contacting the first film member 50-1 and the second contacting portion 187 may not be contacting the second film member 50-2.

In this case, the first head unit 140 may completely bond the second film member 50-2 to the second display panel 10-2 by applying heat and pressure to the second film member 50-2, as shown in FIG. 2E. In this case, the temperature of the first head body 141 may be a second temperature (or a second temperature range). The second temperature may be higher than the first temperature. Alternatively, a lowest value of the second temperature range may be greater than a lowest value of the first temperature range, and a highest value of the second temperature range may be greater than a highest value of the first temperature range. In this case, the second head unit 150 may also apply heat and pressure to the first film member 50-1 to completely bond the first film member 50-1 to the first display panel 10-1. Here, the temperature of the second head body 151 may also be the second temperature (or the second temperature range).

Thus, according to the apparatus 100 for manufacturing a display device and a method of manufacturing the display device, the end of the film member 50 may be held or heat and pressure may be applied to the end of the film member 50 before the film member 50 is formally bonded to the display panel 10, thereby preventing the end of the film member 50 from being bent.

In the apparatus 100 and the method, it is possible to uniformly maintain the location of the end of the film member 50, and thus the film member 50 may be precisely adhered to the display panel 10 and bonding quality may improve.

Also, in the apparatus 100 and the method, a plurality of bonding processes may not be sequentially performed but may be simultaneously performed in two regions, and thus the film member 50 may be efficiently adhered to the display panel 10.

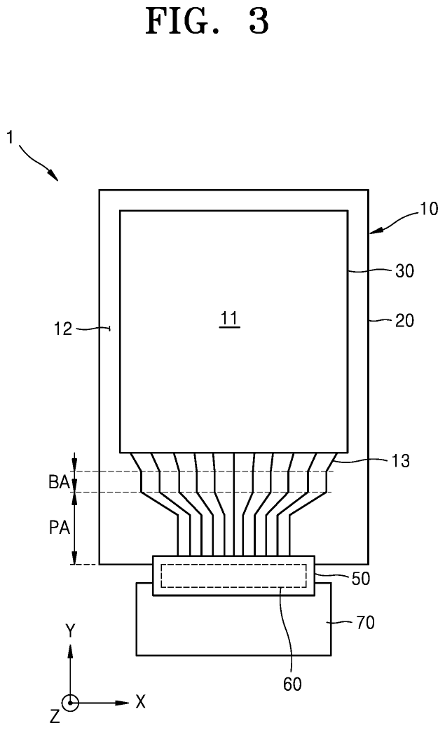

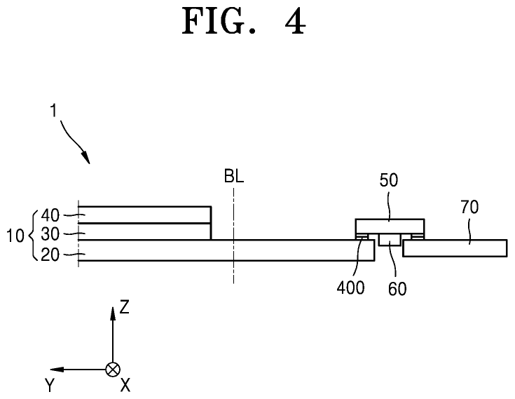

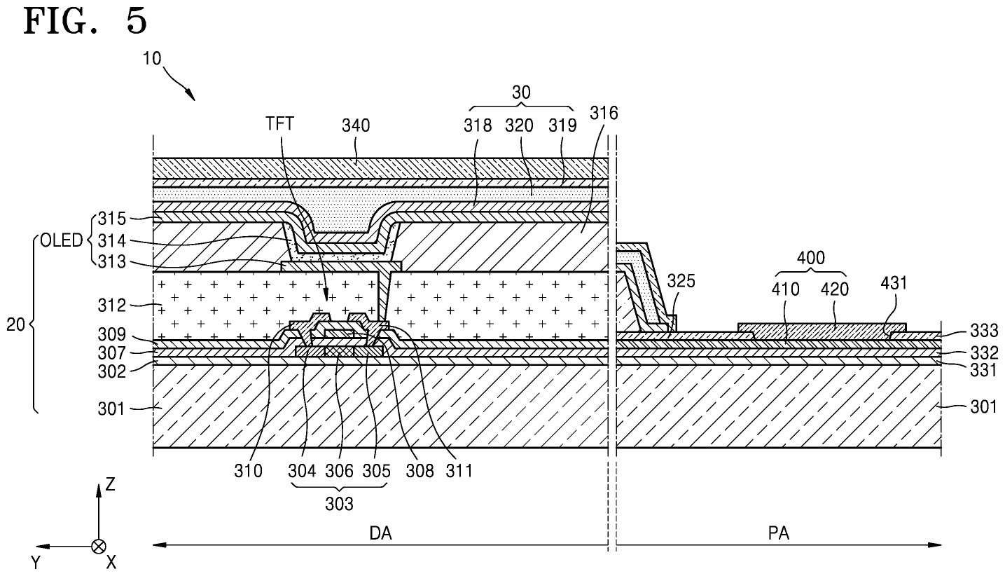

FIG. 3 is a plan view schematically showing a display device 1 according to an embodiment. FIG. 4 is a side view schematically showing a portion of the display device 1 of FIG. 3. FIG. 5 is a cross-sectional view schematically showing a portion of the display panel 10 of FIG. 3.

Referring to FIGS. 3 through 5, the display device 1 includes the display panel 10. According to an embodiment, the display device 1 may be an organic light-emitting display device (“OLED”). However, the display device 1 is not limited thereto, and may include, in addition to an organic light-emitting display apparatus, one of an inorganic light-emitting (“EL”) display apparatus, a quantum dot light-emitting display apparatus, a field emission display apparatus, a surface-conduction electron-emitter display apparatus, and a plasma display apparatus in another embodiment.

The display panel 10 includes a display substrate 20 including a plurality of devices, and a thin-film encapsulation (“TFE”) layer 30 disposed on the display substrate 20. A plurality of thin-film transistors TFT and a plurality of light-emitting devices connected to the thin-film transistors TFT may be disposed on the display substrate 20. A functional film 40, such as a polarization plate, a touch screen, or a cover window, may be disposed on the TFE layer 30.

A display area 11 displaying an image, and a peripheral area 12 extending outside the display area 11 may be disposed on the display panel 10. Here, an image may not be displayed in the peripheral area 12.

The TFE layer 30 may cover the display area 11.

The peripheral area 12 surrounds the display area 11. According to an embodiment, a bending area BA for bending the display panel 10 in one direction, and a pad area PA extending outside the bending area BA may be arranged in the peripheral area 12. However, embodiments are not limited thereto, and the bending area BA may be formed in the display area 11 in another embodiment. According to another embodiment, the peripheral area 12 may not include the bending area BA, and may extend towards the pad area PA. Hereinafter, for convenience of description, a case where the peripheral area 12 includes the bending area BA and the pad area PA, and the bending area BA is formed in the peripheral area 12 will be mainly described.

The bending area BA may have any one of various shapes. According to an embodiment, as shown in FIG. 3, the bending area BA may have a same width (for example, measured in the X-axis direction of FIG. 3) as the display area 11 and the peripheral area 12. According to another embodiment, although not shown in FIG. 3, a width of the bending area BA may decrease away from the display area 11. Also, the width of the bending area BA may be uniform at a certain distance from a portion of the bending area BA, which is connected to the display area 11. In this case, a side edge of the bending area BA may be round.

The display panel 10 may be folded in one direction based on a bending line that is a reference line arranged in the bending area BA. Here, the bending line is arranged inside the bending area BA based on FIG. 3, and in the X-axis direction of FIG. 3. However, embodiments are not limited thereto, and the display area 11 and the pad area PA may be connected to each other without the bending area BA in another embodiment. In other words, the display panel 10 may be configured to be rigid without the bending line. Hereinafter, for convenience of description, the display panel 10 capable of being folded in one direction based on the bending line will be mainly described.

The pad area PA may be arranged at an edge of the display substrate 20. A plurality of pad terminals 400 may be arranged in the pad area PA. The plurality of pad terminals 400 may be spaced apart from each other in the X-axis and Y-axis directions of the display substrate 20. The pad terminal 400 may be connected to a wire 13 extending from the display area 11.

The plurality of pad terminals 400 may be electrically connected to a display device driving unit (not shown) through the film member 50.

The display device driving unit includes a driving circuit, and may be a chip-on-film (“COF”). However, the display device driving unit is not limited thereto, and for example, the display device driving unit may be a chip-on-plastic (“COP”) or a chip-on-glass (“COG”) in another embodiment.

The display device driving unit includes the film member 50 in which a circuit wire is patterned, a driving chip 60 disposed on the film member 50, and a plurality of driving terminals (not shown) disposed below the driving chip 60. The film member 50 and the driving chip 60 may be electrically connected to each other.

The film member 50 may be electrically connected to a circuit board 70. The circuit board 70 may be a flexible printed circuit board (“FPCB”).

The plurality of pad terminals 400 and a terminal of the film member 50 may be electrically connected to each other, and the film member 50 and the plurality of driving terminals may be electrically connected to each other. In other words, the pad terminal 400 and the terminal of the film member 50, which are arranged to correspond to each other, may be directly or indirectly electrically connected to each other. When the pad terminal 400 and the terminal of the film member 50 are indirectly connected to each other, the pad terminal 400 and the terminal of the film member 50 may be electrically connected through an anisotropic conductive film as described above.

A substrate 301 may include a display area DA provided in the display area 11, and the pad area PA provided in the peripheral area 12.

The substrate 301 may be a flexible glass substrate, a flexible polymer substrate, a rigid glass substrate, or a rigid polymer substrate. The substrate 301 may be transparent, semi-transparent, or opaque. Hereinafter, for convenience of description, a case where the substrate 301 is a flexible polymer substrate will be mainly described in detail.

A barrier layer 302 may be disposed on the substrate 301. The barrier layer 302 may cover a top surface of the substrate 301. The barrier layer 302 may be an organic layer or an inorganic layer. Also, the barrier layer 302 may be a single layer or a multilayer.

At least one thin-film transistor TFT may be arranged in the display area DA. According to an embodiment, the number of thin-film transistors TFT is not limited to one.

A semiconductor active layer 303 may be disposed on the barrier layer 302. The semiconductor active layer 303 includes a source region 304 and a drain region 305, which are arranged by doping N-type impure ions or P-type impure ions. A channel region 306 between the source region 304 and the drain region 305 may be a region where impurities are not doped. The semiconductor active layer 303 may be an organic semiconductor, an inorganic semiconductor, or amorphous silicon. According to another embodiment, the semiconductor active layer 303 may be an oxide semiconductor.

A gate insulating layer 307 may be deposited on the semiconductor active layer 303. The gate insulating layer 307 may be an organic layer and/or an inorganic layer. Also, the gate insulating layer 307 may be a single layer or multiplayer including at least one of an organic layer or an inorganic layer. Here, the gate insulating layer 307 is not limited thereto, and may be modified into any one of various shapes.

A gate electrode 308 may be disposed on the gate insulating layer 307. The gate electrode 308 may be formed of a conductive metal material. For example, the gate electrode 308 includes at least one of molybdenum (Mo), aluminum (Al), copper (Cu), or titanium (Ti). The gate electrode 308 may be a single layer and/or multiplayer including at least one of Mo, Al, Cu, or Ti. The gate electrode 308 is not limited thereto, and may include any one of various materials and may be modified into any one of various shapes.

An interlayer insulating layer 309 may be disposed on the gate electrode 308. The interlayer insulating layer 309 may be an organic layer or an inorganic layer.

A source electrode 310 and a drain electrode 311 may be disposed on the interlayer insulating layer 309. A contact hole may be formed by removing a part of the gate insulating layer 307 and a part of the interlayer insulating layer 309, and the source electrode 310 may be electrically connected to the source region 304 and the drain electrode 311 may be electrically connected to the drain region 305 through the contact hole.

The source electrode 310 and the drain electrode 311 may be formed of a metal material having excellent conductivity. For example, the source electrode 310 and the drain electrode 311 include at least one of Mo, Al, Cu, or Ti. The source electrode 310 and the drain electrode 311 may be a single layer or multiplayer including at least one of Mo, Al, Cu, or Ti. For example, the source electrode 310 and the drain electrode 311 may have a stack structure of Ti/Al/Ti. Here, at least one of the source electrode 310 or the drain electrode 311 is not limited thereto, and may include any one of various materials and may have any one of various structures.

A protection layer 312 may be disposed on the source electrode 310 and the drain electrode 311. The protection layer 312 may be an organic layer or an inorganic layer. The protection layer 312 may be a passivation layer or a planarization layer. One of the passivation layer and the planarization layer may be omitted.

The thin-film transistor TFT may be electrically connected to an organic light-emitting display device OLED.

The organic light-emitting display device OLED may be disposed on the protection layer 312. The organic light-emitting display device OLED includes a first electrode 313, an intermediate layer 314, and a second electrode 315.

The first electrode 313 may function as an anode, and may include any one of various conductive materials. The first electrode 313 includes a transparent electrode or a reflective electrode. For example, when the first electrode 313 is used as a transparent electrode, the first electrode 313 includes a transparent conductive layer. When the first electrode 313 is used as a reflective electrode, the first electrode 313 includes a reflective layer and a transparent conductive layer disposed on the reflective layer. According to an embodiment, the first electrode 313 may have a stack structure of TIO/Ag/TIO.

Such a first electrode 313 may be connected to the drain electrode 311 or the source electrode 310. Hereinafter, for convenience of description, a case where the first electrode 313 is connected to the drain electrode 311 will be mainly described in detail.

A pixel-defining layer 316 may be disposed on the protection layer 312. The pixel-defining layer 316 may cover a part of the first electrode 313. The pixel-defining layer 316 defines an emission area of each sub-pixel by surrounding an edge of the first electrode 313. The first electrode 313 may be patterned for each sub-pixel. The pixel-defining layer 316 may be an organic layer and/or an inorganic layer. The pixel-defining layer 316 may be a single layer or multiplayer including at least one of an organic layer or an inorganic layer. The pixel-defining layer 316 is not limited thereto, and may include any one of various materials and may have any one of various shapes.

The intermediate layer 314 may be disposed on a region of the first electrode 313, which is exposed by etching a part of the pixel-defining layer 316. The intermediate layer 314 may be formed via a deposition process.

The intermediate layer 314 may include an organic emission layer.

As another example, the intermediate layer 314 may include the organic emission layer and further include at least one of a hole injection layer (“HIL”), a hole transport layer (“HTL”), an electron transport layer (“ETL”), or an electron injection layer (“EIL”).

According to an embodiment, the intermediate layer 314 may include the organic emission layer and further include other various functional layers.

The second electrode 315 may be disposed on the intermediate layer 314.

The second electrode 315 may function as a cathode. The second electrode 315 includes a transparent electrode or a reflective electrode. For example, when the second electrode 315 is used as a transparent electrode, the second electrode 315 includes a metal layer and a transparent conductive layer disposed on the metal layer. When the second electrode 315 is used as a reflective electrode, the second electrode 315 includes a metal layer.

According to an embodiment, a plurality of sub-pixels may be formed on the substrate 301. For example, red, green, blue, or white color may be realized for each sub-pixel. However, embodiments are not limited thereto.

The TFE layer 30 may cover the organic light-emitting display device OLED.

In the TFE layer 30, an inorganic layer and an organic layer may be alternately stacked. For example, a first inorganic layer 318, an organic layer 320, and a second inorganic layer 319 may be sequentially stacked on the organic light-emitting display device OLED. A stack structure of an inorganic layer and an organic layer provided in the TFE layer 30 may vary.

A touch screen 340 may be disposed on the TFE layer 30. According to an embodiment, the touch screen 340 may be an electrostatic capacitive type touch screen. In detail, a base layer (not shown) may be disposed on the TFE layer 30. A plurality of touch electrode wires (not shown) may be disposed on the base layer. According to an embodiment, the touch electrode wire may have a stack structure of Ti/Al/Ti. According to another embodiment, the touch screen 340 may not include the base layer. The touch electrode wire may be covered by a touch electrode insulating layer (not shown). The touch electrode insulating layer may be an organic layer or an inorganic layer.

A first insulating layer 331 may be disposed on the substrate 301 in the pad area PA. The first insulating layer 331 may be arranged on a same layer as the barrier layer 302. In other words, the first insulating layer 331 and the barrier layer 302 may be formed of a same material through a same process.

A second insulating layer 332 may be disposed on the first insulating layer 331. The second insulating layer 332 may be arranged on a same layer as the gate insulating layer 307. In other words, the second insulating layer 332 and the gate insulating layer 307 may be formed of a same material through a same process.

A first conductive layer 410 included in each pad terminal 400 may be disposed on the second insulating layer 332. The first conductive layer 410 may be electrically connected to a wire 325 extracted from the display area DA. The first conductive layer 410 may be arranged on a same layer as the gate electrode 308. In other words, the first conductive layer 410 and the gate electrode 308 may be formed of a same material through a same process. The first conductive layers 410 may be spaced apart from each other in one direction of the substrate 301.

A third insulating layer 333 may be disposed on the first conductive layer 410. The third insulating layer 333 may be arranged on a same layer as the interlayer insulating layer 309. The third insulating layer 333 and the interlayer insulating layer 309 may be formed of a same material through a same process. According to an embodiment, the third insulating layer 333 may be an organic layer or an inorganic layer.

The third insulating layer 333 may cover at least a part of the first conductive layer 410. A contact hole 431 may be formed on the first conductive layer 410 by removing a part of the third insulating layer 333. A top surface of the first conductive layer 410 may be externally exposed in a region where the contact hole 431 is formed.

A second conductive layer 420 may be disposed on the first conductive layer 410. The second conductive layer 420 may be disposed in an island shape on the first conductive layer 410. According to another embodiment, the second conductive layer 420 may be electrically connected to the wire 325 extracted from the display area DA.

The second conductive layer 420 may be arranged on a same layer as the source electrode 310 and the drain electrode 311. In other words, the second conductive layer 420 may be formed of a same material through a same process as the source electrode 310 and the drain electrode 311. According to an embodiment, the second conductive layer 420 may include a plurality of layers and have a stack structure of a layer including at least one of Al or Ti. Various examples of the stack structure of the second conductive layer 420 include Al/Ti/Al and Ti/Al/Ti. Here, the second conductive layer 420 is not limited thereto, and may include any one of various materials or may have any one of various structures.

Referring to FIG. 5, the second conductive layer 420 may be electrically connected to the first conductive layer 410 through the contact hole 431. In other words, the second conductive layer 420 may be electrically connected to the first conductive layer 410 in a region without the third insulating layer 333. The first conductive layer 410 and the second conductive layer 420 may form a contact portion in a region where the contact hole 431 is arranged.

The second conductive layer 420 may extend throughout a partial region of the first conductive layer 410 exposed through the contact hole 431 and a region where the third insulating layer 333 covering the first conductive layer 410 is arranged.

The first conductive layer 410 and the second conductive layer 420 are not electrically connected to each other throughout an entire region, but may be connected to each other through the contact hole 431 formed by removing a part of the third insulating layer 333. A part of the second conductive layer 420 may be arranged in a region of the first conductive layer 410 exposed through the contact hole 431, and another part of the second conductive layer 420 may be disposed on the third insulating layer 333.

The terminal of the film member 50 may be electrically connected to the pad terminal 400. Also, the film member 50 may be electrically connected to the driving terminal. A circuit pattern may be disposed below the driving chip 60. The driving terminal may include at least one of gold (Au), nickel (Ni), or tin (Sn). The driving terminal is not limited thereto, and may include any one of various materials.

According to an embodiment, the first conductive layer 410 and the second conductive layer 420 are not only disposed on a same layer as the gate electrode 308, the source electrode 310, and the drain electrode 311, but also disposed on a same layer as another metal layer disposed on the substrate 301 of FIG. 5, for example, metal layers selected from among the first electrode 313, the second electrode 315, and a touch electrode.

According to an embodiment, the third insulating layer 333 may be not only disposed on a same layer as the interlayer insulating layer 309, but also disposed on a same layer as an insulating layer selected from among the gate insulating layer 307, the protection layer 312, the pixel-defining layer 316, the TFE layer 30, and the touch electrode insulating layer, which are patterned on the substrate 301 of FIG. 5.

The plurality of pad terminals 400 electrically connected to the terminal of the film member 50 may be arranged in the pad area PA. The plurality of pad terminals 400 may be spaced apart from each other in one direction of the substrate 301.

The film member 50 and the display panel 10 may be bonded to each other through the apparatus 100 described in FIGS. 1 through 2E.

Accordingly, the display panel 10 and the film member 50 are accurately bonded, and thus the display device 1 may provide a clear image without malfunction.

In an apparatus and method for manufacturing a display device, according to embodiments, a film member may be accurately attached to a display panel.

In an apparatus and method for manufacturing a display device, according to embodiments, attachment quality may be improved by attaching a film member to a display panel while maintaining a flat state of the film member.

In an apparatus and method for manufacturing a display device, according to embodiments, manufacturing processes may be simplified and a manufacturing time may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a stage where a display panel is arranged;
a vision unit configured to capture images of an alignment mark of the display panel and an alignment mark of a film member;
a fixing unit configured to transfer the film member and change a location of the film member based on the images captured by the vision unit such that an end of the film member is arranged on a pad portion of the display panel; and
a loading unit connected to the fixing unit and configured to press the film member by selectively contacting the end of the film member.

2. The apparatus of claim 1, wherein the loading unit comprises:
a contacting portion to which the end of the film member is selectively fixed;
a first linear driving unit configured to linearly move the contacting portion in a first direction by being connected to the contacting portion; and
a second linear driving unit connected to the first linear driving unit and the fixing unit, and configured to linearly move the first linear driving unit in a second direction.

3. The apparatus of claim 2, wherein the contacting portion comprises an adhesive chuck or a vacuum chuck.

4. The apparatus of claim 1, further comprising a first head unit configured to apply heat and pressure to the film member by being disposed on an upper portion of the stage, and bond the film member to the display panel.

5. The apparatus of claim 4, further comprising a second head unit spaced apart from the first head unit, and configured to apply heat and pressure to the film member and bond the film member to the display panel.

6. The apparatus of claim 5, wherein the first head unit and the second head unit are arranged in a diagonal direction from each other with respect to a transfer direction of the stage.

7. The apparatus of claim 5, wherein the stage comprises:
a first main stage configured to move linearly; and
a second main stage configured to move linearly and spaced apart from the first main stage.

8. The apparatus of claim 7, wherein a location of the first main stage and a location of the second main stage independently change from each other.

9. The apparatus of claim 5, wherein a temperature applied by the first head unit to the film member is different from a temperature applied by the second head unit to the film member.

10. The apparatus of claim 1, wherein the loading unit applies heat to the film member.

11. A method of manufacturing a display device, the method comprising:
contacting a film member to a display panel;
pressing the film member while applying, by a first head unit, heat to the film member; and
pressing the film member while applying, by a second head unit, heat to a portion of the film member pressed by the first head unit.

12. The method of claim 11, further comprising transferring the display panel to which the film member is attached, from one of the first head unit and the second head unit to another of the first head unit and the second head unit.

13. The method of claim 11, wherein the first head unit and the second head unit are arranged in a diagonal direction from each other with respect to a transfer direction of the display panel.

14. The method of claim 11, further comprising capturing images of an alignment mark of the film member and an alignment mark of the display panel.

15. The method of claim 14, further comprising changing a location of at least one of the film member or the display panel by comparing the alignment mark of the film member and the alignment mark of the display panel.

16. The method of claim 11, further comprising pressing one surface of the film member by contacting a loading unit to the one surface of the film member.

17. The method of claim 16, further comprising separating the loading unit from the one surface of the film member after pressing the one surface of the film member.

18. The method of claim 16, wherein the loading unit comprises:
a contacting portion to which an end of the film member is selectively fixed;
a first linear driving unit configured to linearly move the contacting portion in a first direction by being connected to the contacting portion; and
a second linear driving unit connected to the first linear driving unit and a fixing unit, and configured to linearly move the first linear driving unit in a second direction.

19. The method of claim 18, wherein the contacting portion comprises one of a vacuum chuck or an adhesive chuck, which fixes the one surface of the film member.

20. The method of claim 11, wherein a temperature of the first head unit is different from a temperature of the second head unit.
